(19) United States
(12) Patent Application Publication
(10) Pub. No.: US 2026/0239998 A1
(43) Pub. Date: Aug. 13, 2026

(54) CHIP PACKAGE STRUCTURE WITH DIELECTRIC LAYER AND METHOD FOR FORMING THE SAME

(71) Applicant: Taiwan Semiconductor Manufacturing Company, Ltd., Hsinchu (TW)

(72) Inventors: Yu-Chieh YUNG, Hsinchu City (TW); Yu-Ching WANG, Kaohsiung City (TW); Peng-Hao HSU, Hsinchu City (TW); Shih-Wei CHEN, Hsinchu County (TW); Meng-Tsan LEE, Hsinchu (TW); An-Jhih SU, Taoyuan City (TW)

(73) Assignee: Taiwan Semiconductor Manufacturing Company, Ltd., Hsinchu (TW)

(21) Appl. No.: 19/048,238

(22) Filed: Feb. 7, 2025

(51) Int. Cl. H01L 21/48; H01L 21/56; H01L 25/00

(52) U.S. Cl. CPC H10W 70/05; H10W 74/01; H10W 90/00

(57) ABSTRACT

A method for forming a chip package structure is provided. The method includes forming a first wiring layer over a first dielectric layer. The method includes forming a second dielectric layer over the first dielectric layer and the first wiring layer. A first peripheral portion of the second dielectric layer covers a first sidewall of the first dielectric layer. The method includes forming a second wiring layer over the second dielectric layer. The method includes disposing a chip over the second wiring layer. The chip is electrically connected to the second wiring layer. The method includes removing the first peripheral portion of the second dielectric layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform, and packaging processes for packaging semiconductor devices with small feature sizes also continue to become more difficult to perform.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1G are cross-sectional views of various stages of a process for forming a chip package structure, in accordance with some embodiments.

FIG. 1C-1 is a top view of the chip package structure of FIG. 1C, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x ±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the chip package structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

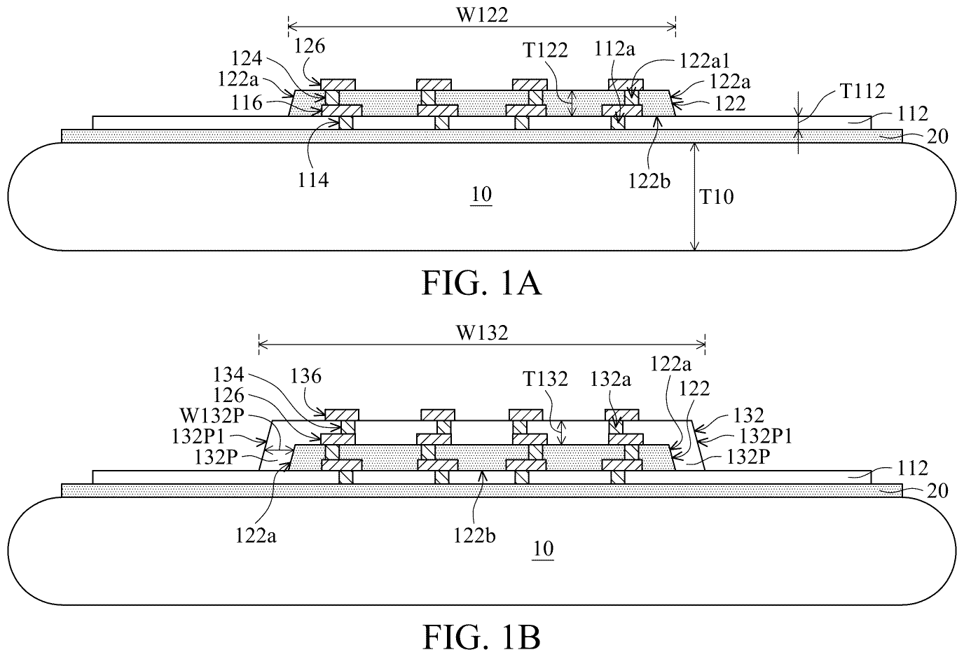

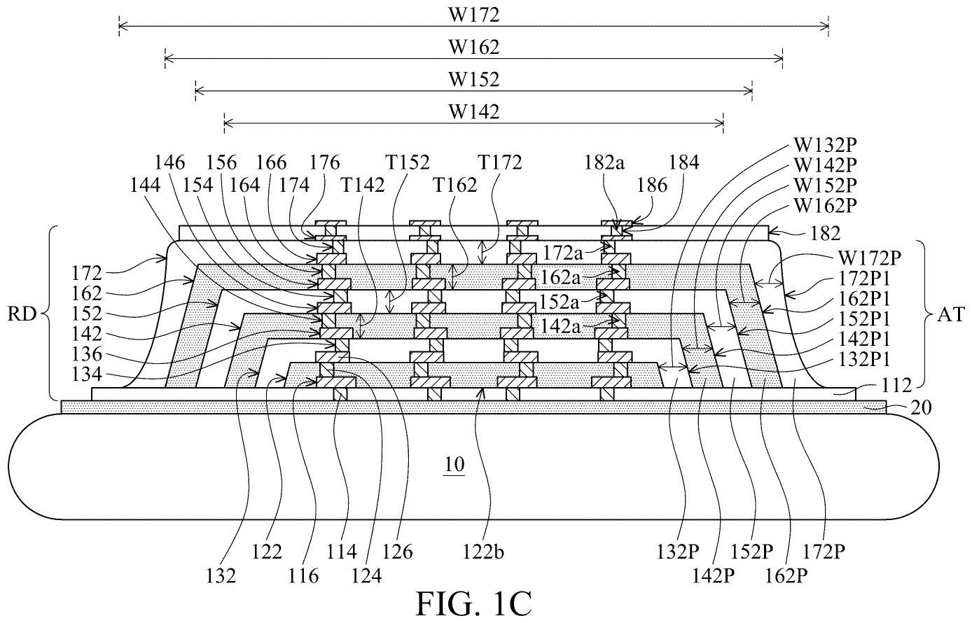

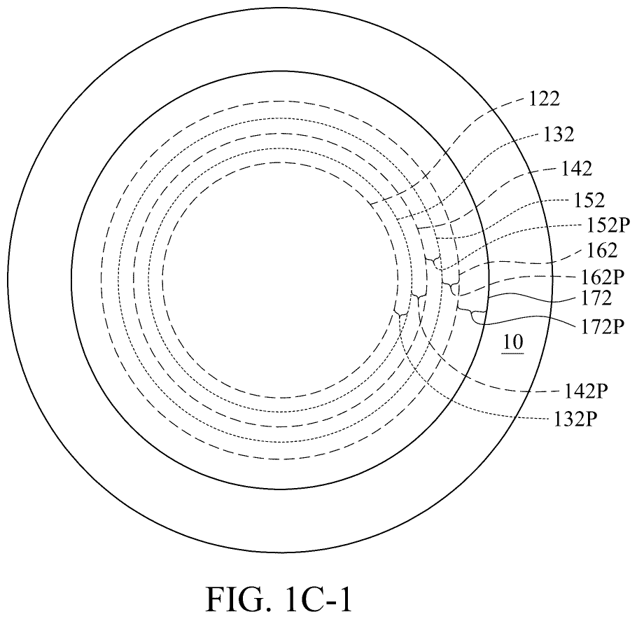

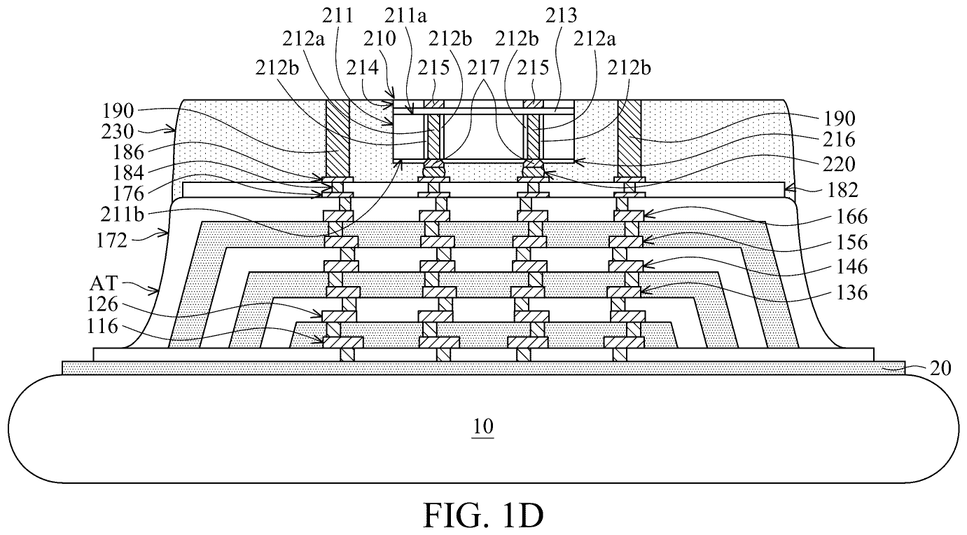

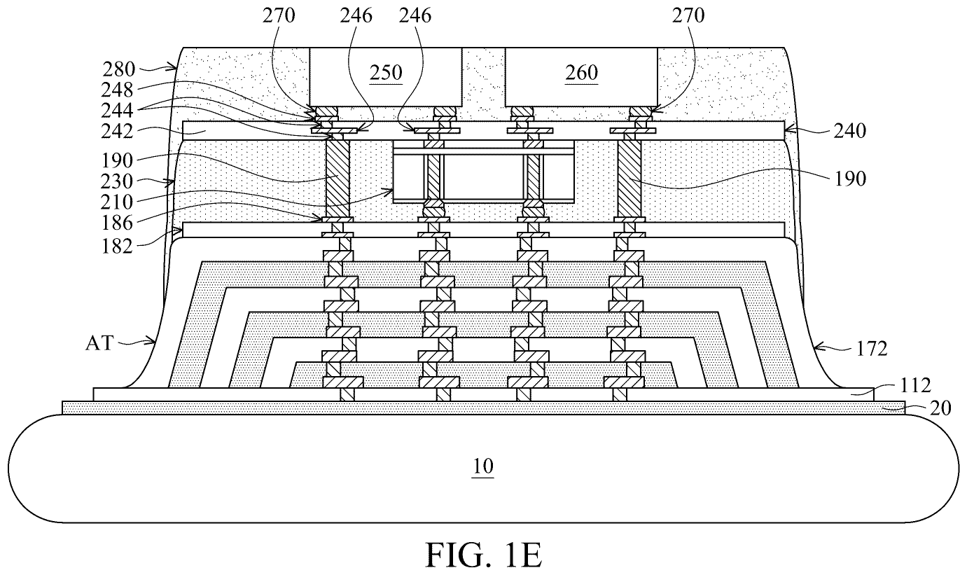

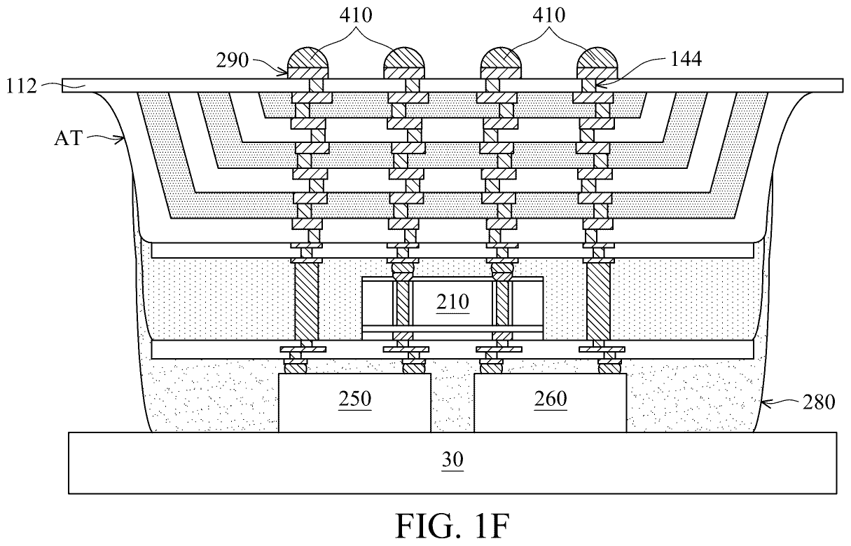

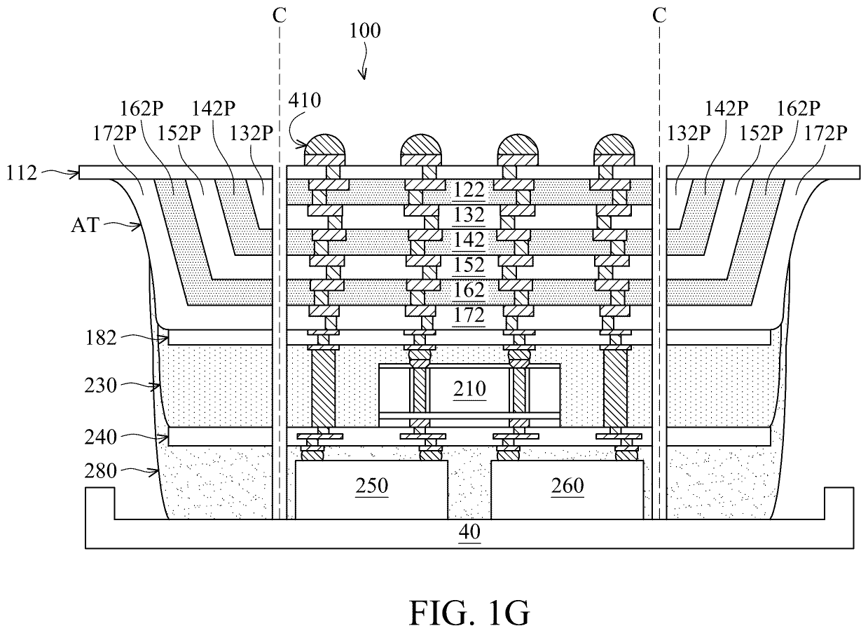

FIGS. 1A-1G are cross-sectional views of various stages of a process for forming a chip package structure, in accordance with some embodiments. As shown in FIG. 1A, a carrier substrate 10 is provided, in accordance with some embodiments.

The carrier substrate 10 is made of a rigid material such as glass, in accordance with some embodiments. The thickness T10 of the carrier substrate 10 ranges from about 800 μm to about 1200 μm, in accordance with some embodiments.

As shown in FIG. 1A, a release film 20 is formed over the carrier substrate 10, in accordance with some embodiments. The release film 20 includes a light-to-heat conversion release film, in accordance with some embodiments. The release film 20 is made of a polymer material, in accordance with some embodiments.

As shown in FIG. 1A, an insulating layer 112 is formed over the release film 20, i accordance with some embodiments. The insulating layer 112 has a thickness T112 ranging from about 10 μm to 30 μm, in accordance with some embodiments. The insulating layer 112 is made of a polymer material such as polyimide, in accordance with some embodiments.

As shown in FIG. 1A, portions of the insulating layer 112 are removed to form holes 112a in the insulating layer 112, in accordance with some embodiments. The removal process includes a photolithography process and an etching process, in accordance with some embodiments. If the insulating layer 112 is made of a photoresist material, the removal process includes a photolithography process, in accordance with some embodiments.

As shown in FIG. 1A, conductive vias 114 are formed in the holes 112a of the insulating layer 112, and a wiring layer 116 is formed over the conductive vias 114 and the insulating layer 112, in accordance with some embodiments.

The conductive vias 114 and the wiring layer 116 are made of a conductive material, such as metal (e.g., copper, aluminum, gold, silver, tin, or tungsten) or alloys thereof, in accordance with some embodiments. The conductive vias 114 and the wiring layer 116 are formed using a plating process such as an electrical plating process, in accordance with some embodiments.

As shown in FIG. 1A, a dielectric layer 122 is formed over the insulating layer 112 and the wiring layer 116, in accordance with some embodiments. The formation of the dielectric layer 122 includes laminating the dielectric layer 122 over the insulating layer 112 and the wiring layer 116; curing the dielectric layer 122 to harden the dielectric layer 122; and grinding the hardened dielectric layer 122 to planarize the top surface of the hardened dielectric layer 122, in accordance with some embodiments.

The curing temperature of the dielectric layer 122 ranges from about 200° C. to about 260° C., in accordance with some embodiments. If the curing temperature is higher than 260° C., the curing temperature is too high and the dielectric layer 122 may be damaged. If the curing temperature is below 200° C., the curing temperature is too low to harden the dielectric layer 122, in accordance with some embodiments.

Since the material of the dielectric layer 122 has a little fluidity before the curing process is performed, the sidewalls 122a of the dielectric layer 122 are sloped sidewalls, in accordance with some embodiments. The width W122 of the dielectric layer 122 increases toward a bottom surface 122b of the dielectric layer 122, in accordance with some embodiments. The average width of the dielectric layer 122 ranges from about 290 mm to 295 mm, in accordance with some embodiments.

The thickness T122 of the dielectric layer 122 ranges from about 30 μm to 50 μm, in accordance with some embodiments. If the thickness T122 is greater than 50 μm, the thickness T122 may be too large to reduce the thickness of the chip package structure with the dielectric layer 122. If the thickness T122 is less than 30 μm, the thickness T122 may be too thin to accommodate the wiring layer 116 and the conductive vias 124.

The thermal expansion coefficient of the dielectric layer 122 is less than the thermal expansion coefficient of the insulating layer 112, in accordance with some embodiments. Therefore, the dielectric layer 122 can reduce the warpage of the insulating layer 112, in accordance with some embodiments. The dielectric layer 122 is also referred to as an antiwarpage layer, in accordance with some embodiments. The hardness of the dielectric layer 122 is greater than the hardness of the insulating layer 112, in accordance with some embodiments.

The dielectric layer 122 is made of a polymer material and a filler material, in accordance with some embodiments. The polymer material includes resin or the like, in accordance with some embodiments. The filler material includes oxides (e.g., SiO₂) or the like, in accordance with some embodiments.

As shown in FIG. 1A, portions of the dielectric layer 122 are removed to form holes 122a1 in the dielectric layer 122, in accordance with some embodiments. The removal process includes a photolithography process and an etching process, in accordance with some embodiments.

As shown in FIG. 1A, conductive vias 124 are formed in the holes 122a1 of the dielectric layer 122, and a wiring layer 126 is formed over the conductive vias 124 and the dielectric layer 122, in accordance with some embodiments.

The conductive vias 124 and the wiring layer 126 are made of a conductive material, such as metal (e.g., copper, aluminum, gold, silver, tin, or tungsten) or alloys thereof, in accordance with some embodiments. The conductive vias 124 and the wiring layer 126 are formed using a plating process such as an electrical plating process, in accordance with some embodiments.

As shown in FIG. 1B, a dielectric layer 132 is formed over the dielectric layer 122 and the wiring layer 126, in accordance with some embodiments. The dielectric layer 132 is wrapped around the dielectric layer 122, in accordance with some embodiments.

The dielectric layer 122 is embedded in the dielectric layer 132, in accordance with some embodiments. The dielectric layer 132 is wider than the dielectric layer 122, in accordance with some embodiments. The dielectric layer 132 has a substantially reverse U-shape, in accordance with some embodiments. The dielectric layer 132 has a peripheral portion 132P, in accordance with some embodiments.

The peripheral portion 132P covers the sidewalls 122a of the dielectric layer 122, in accordance with some embodiments. The peripheral portion 132P conformally covers the sidewall 122a of the dielectric layer 122, in accordance with some embodiments. The peripheral portion 132P surrounds the dielectric layer 122, in accordance with some embodiments. The width W132P of the peripheral portion 132P ranges from about 0.3 mm to about 0.7 mm, in accordance with some embodiments.

The peripheral portion 132P of the dielectric layer 132 is thicker than the dielectric layer 122, in accordance with some embodiments. The formation of the dielectric layer 132 includes laminating the dielectric layer 132 over the dielectric layer 122 and the wiring layer 126; curing the dielectric layer 132 to harden the dielectric layer 132; and grinding the hardened dielectric layer 132 to planarize the top surface of the hardened dielectric layer 132, in accordance with some embodiments.

The curing temperature of the dielectric layer 132 ranges from about 200° C. to about 260° C., in accordance with some embodiments. If the curing temperature is higher than 260° C., the curing temperature is too high and the dielectric layer 132 may be damaged. If the curing temperature is below 200° C., the curing temperature is too low to harden the dielectric layer 132, in accordance with some embodiments.

Since the material of the dielectric layer 132 has a little fluidity before the curing process is performed, the peripheral portion 132P has sloped sidewalls 132P1, in accordance with some embodiments. The width W132 of the dielectric layer 132 increases toward the bottom surface 122b of the dielectric layer 122, in accordance with some embodiments. The average width of the dielectric layer 132 ranges from about 291 mm to 296 mm, in accordance with some embodiments.

The thickness T132 of the dielectric layer 132 ranges from about 30 μm to 50 μm, in accordance with some embodiments. If the thickness T132 is greater than 50 μm, the thickness T132 may be too large to reduce the thickness of the chip package structure with the dielectric layer 132. If the thickness T132 is less than 30 μm, the thickness T132 may be too thin to accommodate the wiring layer 126 and the conductive vias 134.

The thermal expansion coefficient of the dielectric layer 132 is less than the thermal expansion coefficient of the insulating layer 112, in accordance with some embodiments. Therefore, the dielectric layer 132 can reduce the warpage of the insulating layer 112, in accordance with some embodiments. The dielectric layer 132 is also referred to as an antiwarpage layer, in accordance with some embodiments. The hardness of the dielectric layer 132 is greater than the hardness of the insulating layer 112, in accordance with some embodiments.

The dielectric layer 132 is made of a polymer material and a filler material, in accordance with some embodiments. The polymer material includes resin or the like, in accordance with some embodiments. The filler material includes oxides (e.g., SiO₂) or the like, in accordance with some embodiments.

As shown in FIG. 1B, portions of the dielectric layer 132 are removed to form holes 132a in the dielectric layer 132, in accordance with some embodiments. The removal process includes a photolithography process and an etching process, in accordance with some embodiments.

As shown in FIG. 1B, conductive vias 134 are formed in the holes 132a of the dielectric layer 132, and a wiring layer 136 is formed over the conductive vias 134 and the dielectric layer 132, in accordance with some embodiments.

The conductive vias 134 and the wiring layer 136 are made of a conductive material, such as metal (e.g., copper, aluminum, gold, silver, tin, or tungsten) or alloys thereof, in accordance with some embodiments. The conductive vias 134 and the wiring layer 136 are formed using a plating process such as an electrical plating process, in accordance with some embodiments.

FIG. 1C-1 is a top view of the chip package structure of FIG. 1C, in accordance with some embodiments. As shown in FIGS. 1C and 1C-1, a dielectric layer 142 is formed over the dielectric layer 132 and the wiring layer 136, in accordance with some embodiments. The dielectric layer 142 has a substantially reverse U-shape, in accordance with some embodiments.

The dielectric layer 142 has a peripheral portion 142P surrounding the dielectric layer 132, in accordance with some embodiments. The peripheral portion 142P covers the peripheral portion 132P of the dielectric layer 132, in accordance with some embodiments. The width W142P of the peripheral portion 142P ranges from about 0.3 mm to about 0.7 mm, in accordance with some embodiments.

As shown in FIG. 1C-1, the peripheral portion 132P of the dielectric layer 132 has ring shape, in accordance with some embodiments. The peripheral portion 142P of the dielectric layer 142 has a ring shape, in accordance with some embodiments. As shown in FIGS. 1C and 1C-1, the dielectric layer 142 is wrapped around the dielectric layer 132, in accordance with some embodiments.

The dielectric layer 132 is embedded in the dielectric layer 142, in accordance with some embodiments. The dielectric layer 142 is wider than the dielectric layer 132, in accordance with some embodiments. The dielectric layer 142 has a substantially reverse U-shape, in accordance with some embodiments. The dielectric layer 142 has a peripheral portion 142P, in accordance with some embodiments.

The peripheral portion 142P covers the sidewalls 132P1 of the peripheral portion 132P of the dielectric layer 132, in accordance with some embodiments. The peripheral portion 142P conformally covers the sidewalls 132P1, in accordance with some embodiments.

The peripheral portion 142P surrounds the dielectric layer 132, in accordance with some embodiments. The peripheral portion 142P of the dielectric layer 142 is thicker than the peripheral portion 132P of the dielectric layer 132, in accordance with some embodiments.

The formation of the dielectric layer 142 includes laminating the dielectric layer 142 over the dielectric layer 132 and the wiring layer 136; curing the dielectric layer 142 to harden the dielectric layer 142; and grinding the hardened dielectric layer 142 to planarize the top surface of the hardened dielectric layer 142, in accordance with some embodiments.

The curing temperature of the dielectric layer 142 ranges from about 200° C. to about 260° C., in accordance with some embodiments. If the curing temperature is higher than 260° C., the curing temperature is too high and the dielectric layer 142 may be damaged. If the curing temperature is below 200° C., the curing temperature is too low to harden the dielectric layer 142, in accordance with some embodiments.

Since the material of the dielectric layer 142 has a little fluidity before the curing process is performed, the peripheral portion 142P has sloped sidewalls 142P1, in accordance with some embodiments. The width W142 of the dielectric layer 142 increases toward the bottom surface 122b of the dielectric layer 122, in accordance with some embodiments. The average width of the dielectric layer 142 ranges from about 292 mm to 297 mm, in accordance with some embodiments.

The thickness T142 of the dielectric layer 142 ranges from about 30 μm to 50 μm, in accordance with some embodiments. If the thickness T142 is greater than 50 μm, the thickness T142 may be too large to reduce the thickness of the chip package structure with the dielectric layer 142. If the thickness T142 is less than 30 μm, the thickness T142 may be too thin to accommodate the wiring layer 136 and the conductive vias 144.

The thermal expansion coefficient of the dielectric layer 142 is less than the thermal expansion coefficient of the insulating layer 112, in accordance with some embodiments. Therefore, the dielectric layer 142 can reduce the warpage of the insulating layer 112, in accordance with some embodiments. The dielectric layer 142 is also referred to as an antiwarpage layer, in accordance with some embodiments.

The hardness of the dielectric layer 142 is greater than the hardness of the insulating layer 112, in accordance with some embodiments. The dielectric layer 142 is made of a polymer material and a filler material, in accordance with some embodiments. The polymer material includes resin or the like, in accordance with some embodiments. The filler material includes oxides (e.g., SiO₂) or the like, in accordance with some embodiments.

As shown in FIG. 1C, portions of the dielectric layer 142 are removed to form holes 142a in the dielectric layer 142, in accordance with some embodiments. The removal process includes a photolithography process and an etching process, in accordance with some embodiments.

As shown in FIG. 1C, conductive vias 144 are formed in the holes 142a of the dielectric layer 142, and a wiring layer 146 is formed over the conductive vias 144 and the dielectric layer 142, in accordance with some embodiments.

The conductive vias 144 and the wiring layer 146 are made of a conductive material, such as metal (e.g., copper, aluminum, gold, silver, tin, or tungsten) or alloys thereof, in accordance with some embodiments. The conductive vias 144 and the wiring layer 146 are formed using a plating process such as an electrical plating process, in accordance with some embodiments.

As shown in FIGS. 1C and 1C-1, a dielectric layer 152 is formed over the dielectric layer 142 and the wiring layer 146, in accordance with some embodiments. The dielectric layer 152 has a substantially reverse U-shape, in accordance with some embodiments.

The dielectric layer 152 has a peripheral portion 152P surrounding the dielectric layer 142, in accordance with some embodiments. The peripheral portion 152P covers the peripheral portion 142P of the dielectric layer 142, in accordance with some embodiments. The width W152P of the peripheral portion 152P ranges from about 0.3 mm to about 0.7 mm, in accordance with some embodiments.

As shown in FIG. 1C-1, the peripheral portion 152P of the dielectric layer 152 has ring shape, in accordance with some embodiments. As shown in FIGS. 1C and 1C-1, the dielectric layer 152 is wrapped around the dielectric layer 142, in accordance with some embodiments.

The dielectric layer 142 is embedded in the dielectric layer 152, in accordance with some embodiments. The dielectric layer 152 is wider than the dielectric layer 142, in accordance with some embodiments. The dielectric layer 152 has a substantially reverse U-shape, in accordance with some embodiments. The dielectric layer 152 has a peripheral portion 152P, in accordance with some embodiments.

The peripheral portion 152P covers the sidewalls 142P1 of the peripheral portion 142P of the dielectric layer 142, in accordance with some embodiments. The peripheral portion 152P conformally covers the sidewalls 142P1, in accordance with some embodiments.

The peripheral portion 152P surrounds the dielectric layer 142, in accordance with some embodiments. The peripheral portion 152P of the dielectric layer 152 is thicker than the peripheral portion 142P of the dielectric layer 142, in accordance with some embodiments.

The formation of the dielectric layer 152 includes laminating the dielectric layer 152 over the dielectric layer 142 and the wiring layer 146; curing the dielectric layer 152 to harden the dielectric layer 152; and grinding the hardened dielectric layer 152 to planarize the top surface of the hardened dielectric layer 152, in accordance with some embodiments.

The curing temperature of the dielectric layer 152 ranges from about 200° C. to about 260° C., in accordance with some embodiments. If the curing temperature is higher than 260° C., the curing temperature is too high and the dielectric layer 152 may be damaged. If the curing temperature is below 200° C., the curing temperature is too low to harden the dielectric layer 152, in accordance with some embodiments.

Since the material of the dielectric layer 152 has a little fluidity before the curing process is performed, the peripheral portion 152P has sloped sidewalls 152P1, in accordance with some embodiments. The width W152 of the dielectric layer 152 increases toward the bottom surface 122b of the dielectric layer 122, in accordance with some embodiments. The average width of the dielectric layer 152 ranges from about 293 mm to 298 mm, in accordance with some embodiments.

The thickness T152 of the dielectric layer 152 ranges from about 30 μm to 50 μm, in accordance with some embodiments. If the thickness T152 is greater than 50 μm, the thickness T152 may be too large to reduce the thickness of the chip package structure with the dielectric layer 152. If the thickness T152 is less than 30 μm, the thickness T152 may be too thin to accommodate the wiring layer 146 and the conductive vias 154.

The thermal expansion coefficient of the dielectric layer 152 is less than the thermal expansion coefficient of the insulating layer 112, in accordance with some embodiments. Therefore, the dielectric layer 152 can reduce the warpage of the insulating layer 112, in accordance with some embodiments. The dielectric layer 152 is also referred to as an antiwarpage layer, in accordance with some embodiments.

The hardness of the dielectric layer 152 is greater than the hardness of the insulating layer 112, in accordance with some embodiments. The dielectric layer 152 is made of a polymer material and a filler material, in accordance with some embodiments. The polymer material includes resin or the like, in accordance with some embodiments. The filler material includes oxides (e.g., SiO₂) or the like, in accordance with some embodiments.

As shown in FIG. 1C, portions of the dielectric layer 152 are removed to form holes 152a in the dielectric layer 152, in accordance with some embodiments. The removal process includes a photolithography process and an etching process, in accordance with some embodiments.

As shown in FIG. 1C, conductive vias 154 are formed in the holes 152a of the dielectric layer 152, and a wiring layer 156 is formed over the conductive vias 154 and the dielectric layer 152, in accordance with some embodiments.

The conductive vias 154 and the wiring layer 156 are made of a conductive material, such as metal (e.g., copper, aluminum, gold, silver, tin, or tungsten) or alloys thereof, in accordance with some embodiments. The conductive vias 154 and the wiring layer 156 are formed using a plating process such as an electrical plating process, in accordance with some embodiments.

As shown in FIGS. 1C and 1C-1, a dielectric layer 162 is formed over the dielectric layer 152 and the wiring layer 156, in accordance with some embodiments. The dielectric layer 162 has a substantially reverse U-shape, in accordance with some embodiments.

The dielectric layer 162 has a peripheral portion 162P surrounding the dielectric layer 152, in accordance with some embodiments. The peripheral portion 162P covers the peripheral portion 152P of the dielectric layer 152, in accordance with some embodiments. The width W162P of the peripheral portion 162P ranges from about 0.3 mm to about 0.7 mm, in accordance with some embodiments.

As shown in FIG. 1C-1, the peripheral portion 162P of the dielectric layer 162 has ring shape, in accordance with some embodiments. As shown in FIGS. 1C and 1C-1, the dielectric layer 162 is wrapped around the dielectric layer 152, in accordance with some embodiments.

The dielectric layer 152 is embedded in the dielectric layer 162, in accordance with some embodiments. The dielectric layer 162 is wider than the dielectric layer 152, in accordance with some embodiments. The dielectric layer 162 has a substantially reverse U-shape, in accordance with some embodiments. The dielectric layer 162 has a peripheral portion 162P, in accordance with some embodiments.

The peripheral portion 162P covers the sidewalls 152P1 of the peripheral portion 152P of the dielectric layer 152, in accordance with some embodiments. The peripheral portion 162P conformally covers the sidewalls 152P1, in accordance with some embodiments.

The peripheral portion 162P surrounds the dielectric layer 152, in accordance with some embodiments. The peripheral portion 162P of the dielectric layer 162 is thicker than the peripheral portion 152P of the dielectric layer 152, in accordance with some embodiments.

The formation of the dielectric layer 162 includes laminating the dielectric layer 162 over the dielectric layer 152 and the wiring layer 156; curing the dielectric layer 162 to harden the dielectric layer 162; and grinding the hardened dielectric layer 162 to planarize the top surface of the hardened dielectric layer 162, in accordance with some embodiments.

The curing temperature of the dielectric layer 162 ranges from about 200° C. to about 260° C., in accordance with some embodiments. If the curing temperature is higher than 260° C., the curing temperature is too high and the dielectric layer 162 may be damaged. If the curing temperature is below 200° C., the curing temperature is too low to harden the dielectric layer 162, in accordance with some embodiments.

Since the material of the dielectric layer 162 has a little fluidity before the curing process is performed, the peripheral portion 162P has sloped sidewalls 162P1, in accordance with some embodiments. The width W162 of the dielectric layer 162 increases toward the bottom surface 122b of the dielectric layer 122, in accordance with some embodiments. The average width of the dielectric layer 162 ranges from about 294 mm to 299 mm, in accordance with some embodiments.

The thickness T162 of the dielectric layer 162 ranges from about 30 μm to 50 μm, in accordance with some embodiments. If the thickness T162 is greater than 50 μm, the thickness T162 may be too large to reduce the thickness of the chip package structure with the dielectric layer 162. If the thickness T162 is less than 30 μm, the thickness T162 may be too thin to accommodate the wiring layer 156 and the conductive vias 164.

The thermal expansion coefficient of the dielectric layer 162 is less than the thermal expansion coefficient of the insulating layer 112, in accordance with some embodiments. Therefore, the dielectric layer 162 can reduce the warpage of the insulating layer 112, in accordance with some embodiments. The dielectric layer 162 is also referred to as an antiwarpage layer, in accordance with some embodiments.

The hardness of the dielectric layer 162 is greater than the hardness of the insulating layer 112, in accordance with some embodiments. The dielectric layer 162 is made of a polymer material and a filler material, in accordance with some embodiments. The polymer material includes resin or the like, in accordance with some embodiments. The filler material includes oxides (e.g., SiO₂) or the like, in accordance with some embodiments.

As shown in FIG. 1C, portions of the dielectric layer 162 are removed to form holes 162a in the dielectric layer 162, in accordance with some embodiments. The removal process includes a photolithography process and an etching process, in accordance with some embodiments.

As shown in FIG. 1C, conductive vias 164 are formed in the holes 162a of the dielectric layer 162, and a wiring layer 166 is formed over the conductive vias 164 and the dielectric layer 162, in accordance with some embodiments.

The conductive vias 164 and the wiring layer 166 are made of a conductive material, such as metal (e.g., copper, aluminum, gold, silver, tin, or tungsten) or alloys thereof, in accordance with some embodiments. The conductive vias 164 and the wiring layer 166 are formed using a plating process such as an electrical plating process, in accordance with some embodiments.

As shown in FIGS. 1C and 1C-1, a dielectric layer 172 is formed over the dielectric layer 162 and the wiring layer 166, in accordance with some embodiments. The dielectric layer 172 has a substantially reverse U-shape, in accordance with some embodiments.

The dielectric layer 172 has a peripheral portion 172P surrounding the dielectric layer 162, in accordance with some embodiments. The peripheral portion 172P covers the peripheral portion 162P of the dielectric layer 162, in accordance with some embodiments. The width W172P of the peripheral portion 172P ranges from about 0.3 mm to about 0.7 mm, in accordance with some embodiments.

As shown in FIG. 1C-1, the peripheral portion 172P of the dielectric layer 172 has ring shape, in accordance with some embodiments. As shown in FIGS. 1C and 1C-1, the dielectric layer 172 is wrapped around the dielectric layer 162, in accordance with some embodiments.

The dielectric layer 162 is embedded in the dielectric layer 172, in accordance with some embodiments. The dielectric layer 172 is wider than the dielectric layer 162, in accordance with some embodiments. The dielectric layer 172 has a substantially reverse U-shape, in accordance with some embodiments. The dielectric layer 172 has a peripheral portion 172P, in accordance with some embodiments.

The peripheral portion 172P covers the sidewalls 162P1 of the peripheral portion 162P of the dielectric layer 162, in accordance with some embodiments. The peripheral portion 172P conformally covers the sidewalls 162P1, in accordance with some embodiments.

The peripheral portion 172P surrounds the dielectric layer 162, in accordance with some embodiments. The peripheral portion 172P of the dielectric layer 172 is thicker than the peripheral portion 162P of the dielectric layer 162, in accordance with some embodiments.

The formation of the dielectric layer 172 includes laminating the dielectric layer 172 over the dielectric layer 162 and the wiring layer 166; curing the dielectric layer 172 to harden the dielectric layer 172; and grinding the hardened dielectric layer 172 to planarize the top surface of the hardened dielectric layer 172, in accordance with some embodiments.

The curing temperature of the dielectric layer 172 ranges from about 200° C. to about 260° C., in accordance with some embodiments. If the curing temperature is higher than 260° C., the curing temperature is too high and the dielectric layer 172 may be damaged. If the curing temperature is below 200° C., the curing temperature is too low to harden the dielectric layer 172, in accordance with some embodiments.

Since the material of the dielectric layer 172 has a little fluidity before the curing process is performed, the peripheral portion 172P has sloped sidewalls 172P1, in accordance with some embodiments. The width W172 of the dielectric layer 172 increases toward the bottom surface 122b of the dielectric layer 122, in accordance with some embodiments. The average width of the dielectric layer 172 ranges from about 295 mm to 300 mm, in accordance with some embodiments.

The thickness T172 of the dielectric layer 172 ranges from about 30 μm to 50 μm, in accordance with some embodiments. If the thickness T172 is greater than 50 μm, the thickness T172 may be too large to reduce the thickness of the chip package structure with the dielectric layer 172. If the thickness T172 is less than 30 μm, the thickness T172 may be too thin to accommodate the wiring layer 166 and the conductive vias 174.

The thermal expansion coefficient of the dielectric layer 172 is less than the thermal expansion coefficient of the insulating layer 112, in accordance with some embodiments. Therefore, the dielectric layer 172 can reduce the warpage of the insulating layer 112, in accordance with some embodiments. The dielectric layer 172 is also referred to as an antiwarpage layer, in accordance with some embodiments.

The hardness of the dielectric layer 172 is greater than the hardness of the insulating layer 112, in accordance with some embodiments. The dielectric layer 172 is made of a polymer material and a filler material, in accordance with some embodiments. The polymer material includes resin or the like, in accordance with some embodiments. The filler material includes oxides (e.g., SiO₂) or the like, in accordance with some embodiments.

As shown in FIG. 1C, portions of the dielectric layer 172 are removed to form holes 172a in the dielectric layer 172, in accordance with some embodiments. The removal process includes a photolithography process and an etching process, in accordance with some embodiments.

As shown in FIG. 1C, conductive vias 174 are formed in the holes 172a of the dielectric layer 172, and a wiring layer 176 is formed over the conductive vias 174 and the dielectric layer 172, in accordance with some embodiments.

The conductive vias 174 and the wiring layer 176 are made of a conductive material, such as metal (e.g., copper, aluminum, gold, silver, tin, or tungsten) or alloys thereof, in accordance with some embodiments. The conductive vias 174 and the wiring layer 176 are formed using a plating process such as an electrical plating process, in accordance with some embodiments.

As shown in FIG. 1C, an insulating layer 182 is formed over the dielectric layer 172 and the wiring layer 176, in accordance with some embodiments. The insulating layer 182 is made of a polymer material such as polyimide, in accordance with some embodiments. The thermal expansion coefficient of the dielectric layers 122, 132, 142, 152, 162, and 172 is less than the thermal expansion coefficient of the insulating layer 182, in accordance with some embodiments.

Therefore, the dielectric layers 122, 132, 142, 152, 162, and 172 can reduce the warpage of the insulating layer 182, in accordance with some embodiments. The dielectric layers 122, 132, 142, 152, 162, and 172 together form an antiwarpage structure AT, in accordance with some embodiments. The hardness of the dielectric layer 122, 132, 142, 152, 162, or 172 is greater than the hardness of the insulating layer 182, in accordance with some embodiments.

For the sake of simplicity, FIG. 1C-1 omits depicting the insulating layer 182, the insulating layer 112, and the release film 20, in accordance with some embodiments. As shown in FIG. 1C, portions of the insulating layer 182 are removed to form holes 182a in the insulating layer 182, in accordance with some embodiments. The removal process includes a photolithography process and an etching process, in accordance with some embodiments.

As shown in FIG. 1C, conductive vias 184 are formed in the holes 182a of the insulating layer 182, and conductive pads 186 are formed over the conductive vias 184 and the insulating layer 182, in accordance with some embodiments.

The conductive vias 184 and the conductive pads 186 are made of a conductive material, such as metal (e.g., copper, aluminum, gold, silver, tin, or tungsten) or alloys thereof, in accordance with some embodiments. The conductive vias 184 and the conductive pads 186 are formed using a plating process such as an electrical plating process, in accordance with some embodiments.

In some embodiments, the insulating layers 112 and 182, the conductive vias 114, 124, 134, 144, 154, 164, 174, and 184, the wiring layer 116, 126, 136, 146, 156, 176, and 186, and the antiwarpage structure AT together form a redistribution structure RD, in accordance with some embodiments.

As shown in FIGS. 1A-1C, since the width of the dielectric layer 122 is less than (not equal to) the width W132 of the dielectric layer 132, the space surrounding the dielectric layer 122 is saved to accommodate the peripheral portion 132P, thereby preventing the peripheral portion 132P from flowing to the carrier substrate 10, which is exposed by the release film 20, in accordance with some embodiments.

Similarly, the peripheral portions 142P, 152P, 162P, and 172P of the dielectric layers 142, 152, 162, and 172 are also prevented from flowing to the carrier substrate 10, which is exposed by the release film 20, in accordance with some embodiments. Therefore, the yield of the redistribution structure RD is improved, in accordance with some embodiments.

As shown in FIG. 1D, conductive pillars 190 are formed over the conductive pads 186 respectively, in accordance with some embodiments. The conductive pillars 190 are made of a conductive material, such as metal (e.g., copper, aluminum, gold, silver, tin, or tungsten) or alloys thereof, in accordance with some embodiments. The conductive pillars 190 are formed using a plating process such as an electrical plating process, in accordance with some embodiments.

As shown in FIG. 1D, a chip 210 is bonded to the conductive pads 186 through conductive bumps 220, in accordance with some embodiments. The chip 210 is electrically connected to the wiring layers 116, 126, 136, 146, 156, 166, and 176 through the conductive bumps 220 and the conductive pads 186, in accordance with some embodiments.

The chip 210 has a substrate 211, conductive vias 212a, an insulating layer 212b, an interconnect structure 213, a dielectric layer 214, conductive pads 215, and an insulating layer 216, in accordance with some embodiments.

The conductive vias 212a pass through the substrate 211, in accordance with some embodiments. The insulating layer 212b is between the conductive vias 212a and the substrate 211, in accordance with some embodiments. The insulating layer 212b separates the conductive vias 212a from the substrate 211, in accordance with some embodiments.

The interconnect structure 213 is over a front surface 211a of the substrate 211 and the conductive vias 212a, in accordance with some embodiments. The interconnect structure 213 includes a dielectric layer, wiring layers, and conductive vias (not shown), in accordance with some embodiments.

The wiring layers and the conductive vias are in the dielectric layer, in accordance with some embodiments. The conductive vias are electrical connected between the wiring layers and the conductive vias 212a, in accordance with some embodiments.

The dielectric layer 214 is formed over the interconnect structure 213, in accordance with some embodiments. The conductive pads 215 are over the interconnect structure 213 and in the dielectric layer 214, in accordance with some embodiments. The conductive vias of the interconnect structure 213 are electrical connected between the wiring layers and the conductive pads 215, in accordance with some embodiments.

The insulating layer 216 is formed over the back surface 211b of the substrate 211, in accordance with some embodiments. The conductive pads 217 are formed over the conductive vias 212a and pass through the insulating layer 216, in accordance with some embodiments. The conductive pads 217 are electrically connected to the device elements formed in and/or over the substrate 211 in the active regions through the conductive vias 212a and the interconnect structure 213, in accordance with some embodiments.

The substrate 211 includes, for example, a semiconductor substrate. In some embodiments, the substrate 211 is made of an elementary semiconductor material including silicon or germanium in a single crystal structure, a polycrystal structure, or an amorphous structure.

In some other embodiments, the substrate 211 is made of a compound semiconductor, such as silicon carbide, gallium arsenide, gallium phosphide, indium phosphide, indium arsenide, an alloy semiconductor, such as SiGe or GaAsP, or a combination thereof. The substrate 211 may also include multi-layer semiconductors, semiconductor on insulator (SOI) (such as silicon on insulator or germanium on insulator), or a combination thereof.

In some embodiments, the substrate 211 is a device substrate that includes various device elements. In some embodiments, the various device elements are formed in and/or over the substrate 211. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate 211. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 211. The isolation features are used to surround active regions and electrically isolate various device elements formed in and/or over the substrate 211 in the active regions. In some embodiments, the isolation features include shallow trench isolation (STI) features, local oxidation of silicon (LOCOS) features, other suitable isolation features, or a combination thereof.

The conductive vias 212a are made of a conductive material, such as metal (e.g., copper, aluminum, gold, silver, tin, or tungsten) or alloys thereof, in accordance with some embodiments. The insulating layer 212b is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the insulating layer 212b includes a low-k material or a porous dielectric material having a k-value which is lower than that of silicon oxide, or lower than about 3.0 or about 2.5, in accordance with some embodiments.

The dielectric layer of the interconnect structure 213 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments.

The wiring layers and the conductive vias of the interconnect structure 213 are made of a conductive material, such as metal (e.g., copper, aluminum, gold, silver, tin, or tungsten) or alloys thereof, in accordance with some embodiments.

The dielectric layer 214 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 214 includes a low-k material or a porous dielectric material having a k-value which is lower than that of silicon oxide, or lower than about 3.0 or about 2.5, in accordance with some embodiments.

The conductive pads 215 are electrically connected to the device elements formed in and/or over the substrate 211 in the active regions through the interconnect structure 213, in accordance with some embodiments. The conductive pads 215 are made of a conductive material, such as metal (e.g., copper, aluminum, gold, silver, tin, or tungsten) or alloys thereof, in accordance with some embodiments.

The insulating layer 216 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the insulating layer 216 includes a low-k material or a porous dielectric material having a k-value which is lower than that of silicon oxide, or lower than about 3.0 or about 2.5, in accordance with some embodiments. The conductive pads 217 are made of a conductive material, such as metal (e.g., copper, aluminum, gold, silver, tin, or tungsten) or alloys thereof, in accordance with some embodiments.

As shown in FIG. 1D, a molding layer 230 is formed over the insulating layer 182 and surrounds the conductive pillars 190, the chip 210, and the conductive bumps 220, in accordance with some embodiments. The molding layer 230 is made of an insulating material, such as a polymer material (e.g., epoxy), in accordance with some embodiments.

As shown in FIG. 1E, a redistribution layer 240 is formed over the conductive pillars 190, the chip 210, and the molding layer 230, in accordance with some embodiments. The redistribution layer 240 includes a dielectric layer 242, conductive vias 244, a wiring layer 246, and conductive pads 248, in accordance with some embodiments.

The wiring layer 246 and the conductive vias 244 are in the dielectric layer 242, in accordance with some embodiments. The conductive vias 244 are electrically connected between the wiring layer 246, the conductive pillars 190, and the conductive pads 248, in accordance with some embodiments.

The dielectric layer 242 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 242 includes a low-k material or a porous dielectric material having a k-value which is lower than that of silicon oxide, or lower than about 3.0 or about 2.5, in accordance with some embodiments.

The conductive vias 244 are made of a conductive material, such as metal (e.g., copper, aluminum, gold, silver, tin, or tungsten) or alloys thereof, in accordance with some embodiments. The wiring layer 246 is made of a conductive material, such as metal (e.g., copper, aluminum, gold, silver, tin, or tungsten) or alloys thereof, in accordance with some embodiments. The conductive pads 248 are made of a conductive material, such as metal (e.g., copper, aluminum, gold, silver, tin, or tungsten) or alloys thereof, in accordance with some embodiments.

As shown in FIG. 1E, a chip 250 and a chip package 260 are bonded to the conductive pads 248 through conductive bumps 270, in accordance with some embodiments. The chip 250 includes a substrate, a dielectric layer, and wiring layers (not shown), in accordance with some embodiments. The dielectric layer is over the substrate, in accordance with some embodiments. The wiring layers are in the dielectric layer, in accordance with some embodiments.

The substrate includes, for example, a semiconductor substrate. In some embodiments, the substrate is made of an elementary semiconductor material including silicon or germanium in a single crystal structure, a polycrystal structure, or an amorphous structure.

In some other embodiments, the substrate is made of a compound semiconductor, such as silicon carbide, gallium arsenide, gallium phosphide, indium phosphide, indium arsenide, an alloy semiconductor, such as SiGe or GaAsP, or a combination thereof. The substrate may also include multi-layer semiconductors, semiconductor on insulator (SOI) (such as silicon on insulator or germanium on insulator), or a combination thereof.

In some embodiments, the substrate is a device substrate that includes various device elements. In some embodiments, the various device elements are formed in and/or over the substrate. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate. The isolation features are used to surround active regions and electrically isolate various device elements formed in and/or over the substrate in the active regions. In some embodiments, the isolation features include shallow trench isolation (STI) features, local oxidation of silicon (LOCOS) features, other suitable isolation features, or a combination thereof.

The dielectric layer is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer includes a low-k material or a porous dielectric material having a k-value which is lower than that of silicon oxide, or lower than about 3.0 or about 2.5, in accordance with some embodiments.

The wiring layers are electrically connected to the device elements formed in and/or over the substrate in the active regions, in accordance with some embodiments. The wiring layers are made of a conductive material, such as metal (e.g., copper, aluminum, gold, silver, tin, or tungsten) or alloys thereof, in accordance with some embodiments.

The chip package 260 includes a high bandwidth memory (HBM) package, in accordance with some embodiments. The chip package 260 includes chips stacked over a substrate, and the chips and the substrate are electrically connected to each other, in accordance with some embodiments. The conductive bumps 270 are made of a conductive material, such as metal (e.g., tin) or alloys thereof, in accordance with some embodiments.

As shown in FIG. 1E, a molding layer 280 is formed over the redistribution layer 240 and surrounds the chip 250, the chip package 260, and the conductive bumps 270, in accordance with some embodiments. The molding layer 280 is made of an insulating material, such as a polymer material (e.g., epoxy), in accordance with some embodiments.

As shown in FIG. 1F, the chip 250, the chip package 260, and the molding layer 280 are bonded to a carrier substrate 30, in accordance with some embodiments. As shown in FIG. 1F, the carrier substrate 10 and the release film 20 are removed, in accordance with some embodiments. As shown in FIG. 1F, conductive pads 290 are formed over the conductive vias 144 and the insulating layer 112, in accordance with some embodiments.

As shown in FIG. 1F, conductive bumps 410 are formed over the conductive pads 290, in accordance with some embodiments. The conductive bumps 410 are made of a conductive material, such as metal (e.g., tin) or alloys thereof, in accordance with some embodiments.

As shown in FIG. 1G, the carrier substrate 30 is removed, in accordance with some embodiments. As shown in FIG. 1G, the chip 250, the chip package 260, and the molding layer 280 are bonded to a frame 40, in accordance with some embodiments.

As shown in FIG. 1G, a cutting process is performed to cut through the insulating layer 112, the antiwarpage structure AT, the insulating layer 182, the molding layer 230, the redistribution layer 240, and the molding layer 280 along cutting lines C, in accordance with some embodiments.

The peripheral portions 132P, 142P, 152P, 162P, and 172P of the dielectric layers 132, 142, 152, 162, and 172 are removed by the cutting process, in accordance with some embodiments. The peripheral portion of the dielectric layer 122 is also removed by the cutting process, in accordance with some embodiments. In this step, a chip package structure 100 is substantially formed, in accordance with some embodiments.

In accordance with some embodiments, chip package structures and methods for forming the same are provided. The methods (for forming the chip package structure) form a redistribution structure with a first dielectric layer and a second dielectric layer over the first dielectric layer. The first dielectric layer and the second dielectric layer have a little fluidity before a curing process is performed. The first width of the first dielectric layer is less than (not equal to) the second width of the second dielectric layer, therefore the space surrounding the first dielectric layer is saved to accommodate the peripheral portion of the second dielectric layer, thereby preventing the peripheral portion from flowing onto a carrier substrate thereunder. Therefore, the yield of the redistribution structure is improved.

In accordance with some embodiments, a method for forming a chip package structure is provided. The method includes forming a first wiring layer over a first dielectric layer. The method includes forming a second dielectric layer over the first dielectric layer and the first wiring layer. A first peripheral portion of the second dielectric layer covers a first sidewall of the first dielectric layer. The method includes forming a second wiring layer over the second dielectric layer. The method includes disposing a chip over the second wiring layer. The chip is electrically connected to the second wiring layer. The method includes removing the first peripheral portion of the second dielectric layer.

In accordance with some embodiments, a method for forming a chip package structure is provided. The method includes forming a first wiring layer over a first dielectric layer. The method includes forming a second dielectric layer over the first dielectric layer and the first wiring layer. The second dielectric layer has a first substantially reverse U-shape in a first cross-sectional view of the second dielectric layer. The method includes forming a second wiring layer over the second dielectric layer. The method includes disposing a chip over the second wiring layer. The chip is electrically connected to the second wiring layer. The method includes removing a first peripheral portion of the second dielectric layer.

In accordance with some embodiments. a method for forming a chip package structure is provided. The method includes forming a first wiring layer over a first dielectric layer. The method includes forming a second dielectric layer over the first dielectric layer and the first wiring layer. The second dielectric layer has a peripheral portion surrounding the first dielectric layer. The method includes forming a second wiring layer over the second dielectric layer. The method includes disposing a chip over the second wiring layer. The chip is electrically connected to the second wiring layer. The method includes removing the peripheral portion of the second dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a chip package structure, comprising:
forming a first wiring layer over a first dielectric layer;
forming a second dielectric layer over the first dielectric layer and the first wiring layer, wherein a first peripheral portion of the second dielectric layer covers a first sidewall of the first dielectric layer;
forming a second wiring layer over the second dielectric layer;
disposing a chip over the second wiring layer, wherein the chip is electrically connected to the second wiring layer; and
removing the first peripheral portion of the second dielectric layer.

2. The method for forming the chip package structure as claimed in claim 1, wherein the first peripheral portion has a sloped sidewall.

3. The method for forming the chip package structure as claimed in claim 1, wherein the first sidewall of the first dielectric layer is a sloped sidewall.

4. The method for forming the chip package structure as claimed in claim 1, wherein the first peripheral portion of the second dielectric layer conformally covers the first sidewall of the first dielectric layer.

5. The method for forming the chip package structure as claimed in claim 1, wherein the second dielectric layer is wrapped around the first dielectric layer before the first peripheral portion of the second dielectric layer is removed.

6. The method for forming the chip package structure as claimed in claim 1, further comprising:
forming a third dielectric layer over the second dielectric layer and the second wiring layer, wherein a second peripheral portion of the third dielectric layer covers the first peripheral portion of the second dielectric layer, and
the removing of the first peripheral portion of the second dielectric layer further comprises:
removing the second peripheral portion of the third dielectric layer.

7. The method for forming the chip package structure as claimed in claim 1, wherein the second dielectric layer is wider than the first dielectric layer before the first peripheral portion of the second dielectric layer is removed.

8. The method for forming the chip package structure as claimed in claim 1, wherein the second dielectric layer is thicker than the first dielectric layer before the first peripheral portion of the second dielectric layer is removed.

9. The method for forming the chip package structure as claimed in claim 1, further comprising:
forming a third wiring layer over an insulating layer, wherein the first dielectric layer is formed over the third wiring layer and the insulating layer, and a first thermal expansion coefficient of the first dielectric layer is less than a second thermal expansion coefficient of the insulating layer.

10. The method for forming the chip package structure as claimed in claim 9, wherein a first hardness of the first dielectric layer is greater than a second hardness of the insulating layer.

11. A method for forming a chip package structure, comprising:
forming a first wiring layer over a first dielectric layer;
forming a second dielectric layer over the first dielectric layer and the first wiring layer, wherein the second dielectric layer has a first substantially reverse U-shape in a first cross-sectional view of the second dielectric layer;
forming a second wiring layer over the second dielectric layer;
disposing a chip over the second wiring layer, wherein the chip is electrically connected to the second wiring layer; and
removing a first peripheral portion of the second dielectric layer.

12. The method for forming the chip package structure as claimed in claim 11, further comprising:
forming a third dielectric layer over the second dielectric layer and the second wiring layer, wherein the third dielectric layer has a second substantially reverse U-shape in a second cross-sectional view of the third dielectric layer, and
the removing of the first peripheral portion of the second dielectric layer comprises:
removing a second peripheral portion of the third dielectric layer.

13. The method for forming the chip package structure as claimed in claim 12, wherein the second peripheral portion of the third dielectric layer has a sloped sidewall.

14. The method for forming the chip package structure as claimed in claim 12, wherein the second dielectric layer is embedded in the third dielectric layer.

15. The method for forming the chip package structure as claimed in claim 11, further comprising:
forming a third wiring layer over an insulating layer, wherein the first dielectric layer is formed over the third wiring layer and the insulating layer, and a first thermal expansion coefficient of the second dielectric layer is less than a second thermal expansion coefficient of the insulating layer.

16. A method for forming a chip package structure, comprising:
forming a first wiring layer over a first dielectric layer;
forming a second dielectric layer over the first dielectric layer and the first wiring layer, wherein the second dielectric layer has a peripheral portion surrounding the first dielectric layer;
forming a second wiring layer over the second dielectric layer;
disposing a chip over the second wiring layer, wherein the chip is electrically connected to the second wiring layer; and
removing the peripheral portion of the second dielectric layer.

17. The method for forming the chip package structure as claimed in claim 16, wherein the peripheral portion of the second dielectric layer has a ring shape.

18. The method for forming the chip package structure as claimed in claim 16, wherein the first dielectric layer is embedded in the second dielectric layer before the peripheral portion of the second dielectric layer is removed.

19. The method for forming the chip package structure as claimed in claim 16, wherein a first width of the first dielectric layer increases toward a bottom surface of the first dielectric layer before the peripheral portion of the second dielectric layer is removed.

20. The method for forming the chip package structure as claimed in claim 19, wherein a second width of the second dielectric layer increases toward the bottom surface of the first dielectric layer before the peripheral portion of the second dielectric layer is removed.
